(19) United States
(12) Patent Application Publication
(10) Pub. No.: US 2015/0156898 A1
(43) Pub. Date: Jun. 4, 2015

(54) MOBILE TERMINAL

(71) Applicant: LG Electronics Inc., Seoul (KR)

(72) Inventors: Choonghwan SHIN, Seoul (KR); Byunghwa LEE, Seoul (KR)

(73) Assignee: LG ELECTRONICS INC., Seoul (KR)

(21) Appl. No.: 14/243,722

(22) Filed: Apr. 2, 2014

(30) Foreign Application Priority Data
Dec. 4, 2013 (KR) 10-2013-0149930

(51) Int. Cl. H05K 5/02

(52) U.S. Cl. CPC H05K 5/0204

(57) ABSTRACT

There is disclosed a mobile terminal including a case configured to define an exterior appearance thereof; a loading recess formed in an outer surface of the case; and a camera module mountable to and demountable from the loading recess, wherein the camera module includes a body unit comprising a first surface inserted in the loading recess and a second surface exposed in an opposite direction of the first surface; a camera unit arranged in the camera unit; and a connector arranged in the body unit, with connected to the mobile terminal electrically.

### BACKGROUND OF THE DISCLOSURE

1. Field of the Disclosure

Embodiments of the present disclosure relates to a mobile terminal, more particularly, to a mobile terminal which includes a demountable camera module.

2. Discussion of the Related Art

Generally, terminals can be classified into mobile terminals and stationary terminals. In addition, the mobile terminals can be further classified into handheld terminals and vehicle mount terminals.

Further, a mobile terminal can perform various functions such as data and voice communications, capturing images and video via a camera, recording audio, playing music files and outputting music via a speaker system, and displaying images and video on a display.

A mobile terminal is a device which may be configured to perform various functions. Examples of such functions include data and voice communications, capturing images and video via a camera, recording audio, playing music files and outputting music via a speaker system, and displaying images and video on a display. Some terminals include additional functionality which supports game playing, while other terminals are also configured as multimedia players. More recently, mobile terminals have been configured to receive broadcast and multicast signals which permit viewing of contents, such as videos and television programs.

As the functions of the terminal are diversified, the terminal is configured as a multimedia player having multiple functions. Examples of the multiple functions includes capturing images or video, playing music or video files, game playing and receiving broadcast.

Using such a mobile terminal including a camera, a user can capture images or video anytime easily. Such a camera is integrally embedded in a case of the mobile terminal and the user has to hold the mobile terminal directly or put it on an auxiliary stand or rest so as to photograph or record video.

In case the user captures images or video, with holding the mobile terminal directly, the overall weight of the mobile terminal is quite heavy and the volume is also substantially large enough for the user to miss the mobile terminal and cause damage to the mobile terminal disadvantageously.

Accordingly, there are increasing demands on a mobile terminal having a demountable camera from a case to provide a user with convenient and easy usage.

SUMMARY OF THE DISCLOSURE

An object of the present disclosure is to provide a mobile which includes a demountable camera module.

To achieve these objects and other advantages and in accordance with the purpose of the disclosure, as embodied and broadly described herein, a mobile terminal includes a mobile terminal includes a case configured to define an exterior appearance thereof; a loading recess formed in an outer surface of the case; and a camera module mountable to and demountable from the loading recess, wherein the camera module includes a body unit comprising a first surface inserted in the loading recess and a second surface exposed in an opposite direction of the first surface; a camera unit arranged in the camera unit; and a connector arranged in the body unit, with connected to the mobile terminal electrically.

A demounting button may be arranged near the loading recess to demount the camera module from the loading recess.

The connector electrically connected to the camera module may be arranged in the loading recess.

A ratio of the depth of the loading recess to the thickness of the camera module may be 1:05-1:1.5.

The connector of the camera module may be exposed outside via a first surface of the body unit, and the camera unit of the camera module may be exposed outside via a second surface of the body unit.

The connector and the camera unit of the camera module may be exposed outside via a first surface of the body unit together.

The body unit of the camera module may include a first region in which the camera unit is arranged and a second region corresponding to the other region, and the thickness of the first region is different from the thickness of the second region.

The first region in which the camera unit may be arranged is thicker than the second region.

A display unit may be arranged in the second region of the body unit provided in the camera module.

The display unit may be overlapped with the connector of the camera module.

The display unit and the camera unit may be exposed outside via a second surface of the body unit together, and the connector of the camera module may be exposed outside via a first surface of the body unit.

The display unit may be exposed outside via a second surface of the body unit, and the connector and the camera unit of the camera module may be exposed outside via a first surface of the body unit together.

The camera module may further include a battery pack electrically connected to the first surface of the body unit.

The battery pack may include a third region facing a connector of the camera module and a fourth region facing a camera unit of the camera module, and the third region of the battery pack is thicker than the fourth region of the battery pack.

The battery pack may further include a first connector arranged in a front surface of the third region, with connected to the connector of the camera module; and a second connector arranged in a lateral surface of the third region, with connected to an external device electrically.

The loading recess may include a fifth region in which the camera unit of the camera module is loaded and a sixth region in which the connector of the camera module is loaded, and the fifth region of the loading recess is thicker than the sixth region of the loading recess.

A cover sheet may be arranged in the fifth and sixth regions of the loading recess to cover an internal circuit of the mobile terminal, and a support plate may be arranged in the sixth region of the loading recess to support the cover sheet, and the support plate may include an empty central space.

The mobile terminal may further include a control unit configured to switch a power button of the camera module over to a power button of the mobile terminal, when the camera module is mounted to the mobile terminal, and to switch the power button of the mobile terminal over to a camera button.

The mobile terminal may further include a control unit configured to control a video displayed on the display unit to be switched over to a mobile terminal mode from a camera mode, when receiving a mode switch signal from the camera module.

The mobile terminal may further include a camera configured to capture an external environment, wherein the camera of the mobile terminal and the camera unit of the camera module are arranged toward the same direction, and the camera of the mobile terminal and the camera unit of the camera module are spaced apart a predetermined distance from each other.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

### BRIEF DESCRIPTION OF THE DRAWINGS

FIG. 1 is a block diagram of a mobile terminal according to one embodiment of the disclosure;

FIG. 2 is a diagram illustrating an exterior appearance of a mobile terminal according to one embodiment of the disclosure;

FIG. 3 is a diagram illustrating a camera module demounted from a mobile terminal;

FIG. 4 is a diagram illustrating a camera module according to a first embodiment;

FIGS. 5A is a sectional diagram of FIG. 4 along A-A line;

FIG. 5B is an exploded perspective diagram of FIG. 4;

FIG. 6 is a diagram illustrating a camera module according to a second embodiment;

FIG. 7 is a diagram illustrating a battery pack of FIG. 6;

FIGS. 8A, 8B and 8C are diagrams to describe a demounting device provided in a camera module;

FIGS.9, 10 and 11 are diagrams illustrating a cover sheet arranged in a seating recess;

FIG. 12 is a diagram illustrating first embodiment of using a demountable camera module;

FIGS. 13A and 13B are diagrams illustrating a second embodiment of using a demountable camera module;

FIG. 14 is a diagram illustrating a third embodiment of using a demountable camera module;

FIGS. 15A, 15B and 15C are diagrams illustrating a fourth embodiment of using a demountable camera module;

FIGS. 16A, 16B and 16C are diagrams illustrating a fifth embodiment of using a demountable camera module;

FIGS. 17A and 17B are diagrams illustrating a sixth embodiment of using a demountable camera module;

FIGS. 18A and 18B are diagrams illustrating a first embodiment of a user interface provided in the mobile terminal according to the disclosure;

FIGS. 19A, 19B and 19C are diagrams illustrating a second embodiment of a user interface provided in the mobile terminal according to the disclosure;

FIGS. 20A and 20B are diagrams illustrating a third embodiment of a user interface provided in the mobile terminal according to the disclosure;

FIGS. 21A and 21B are diagrams illustrating a fourth embodiment of a user interface provided in the mobile terminal according to the disclosure;

FIGS. 22A and 22B are diagrams illustrating a fifth embodiment of a user interface provided in the mobile terminal according to the disclosure;

FIGS. 23A and 23B are diagrams illustrating a camera module according to a second embodiment of the present disclosure; and

FIG. 24 is a diagram illustrating a mobile terminal having the camera module according to the second embodiment mounted therein.

### DESCRIPTION OF SPECIFIC EMBODIMENTS

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be connected with the other element or intervening elements may also be present. In contrast, when an element is referred to as being “directly connected with” another element, there are no intervening elements present.

A singular representation may include a plural representation unless it represents a definitely different meaning from the context. Terms such as “include” or “has” are used herein and should be understood that they are intended to indicate an existence of several components, functions or steps, disclosed in the specification, and it is also understood that greater or fewer components, functions, or steps may likewise be utilized.

Mobile terminals presented herein may be implemented using a variety of different types of terminals. Examples of such terminals include cellular phones, smart phones, user equipment, laptop computers, digital broadcast terminals, personal digital assistants (PDAs), portable multimedia players (PMPs), navigators, portable computers (PCs), slate PCs, tablet PCs, ultra books, wearable devices (for example, smart watches, smart glasses, head mounted displays (HMDs)), and the like.

By way of non-limiting example only, further description will be made with reference to particular types of mobile terminals. However, such teachings apply equally to other types of terminals, such as those types noted above. In addition, these teachings may also be applied to stationary terminals such as digital TV, desktop computers, and the like.

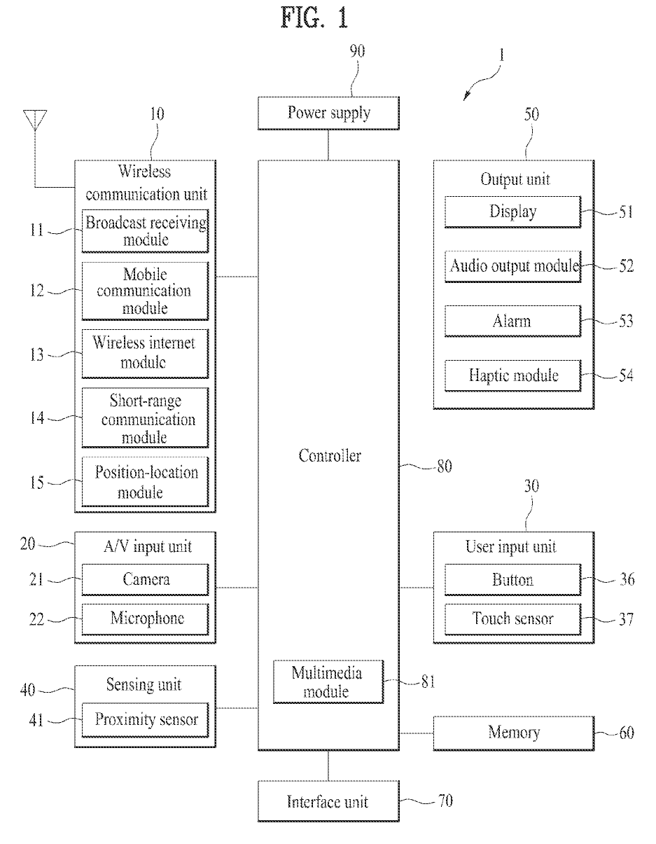

Reference is now made to FIG. 1, where FIG. 1 is a block diagram of a mobile terminal in accordance with the present disclosure.

The mobile terminal 1 is shown having components such as a wireless communication unit 10, an input unit 20, a sensing unit 40, an output unit 50, an interface unit 70, a memory 60, a controller 80, and a power supply unit 90. It is understood that implementing all of the illustrated components is not a requirement, and that greater or fewer components may alternatively be implemented.

Referring now to FIG. 1, the mobile terminal 1 is shown having wireless communication unit 10 configured with several commonly implemented components. For instance, the wireless communication unit 10 typically includes one or more components which permit wireless communication between the mobile terminal 1 and a wireless communication system or network within which the mobile terminal is located.

The wireless communication unit 10 typically includes one or more modules which permit communications such as wireless communications between the mobile terminal 1 and a wireless communication system, communications between the mobile terminal 1 and another mobile terminal, communications between the mobile terminal 1 and an external server. Further, the wireless communication unit 10 typically includes one or more module which connect the mobile terminal 1 to one or more networks. To facilitate such communications, the wireless communication unit 10 includes one or more of a broadcast receiving module 11, a mobile communication module 12, a wireless Internet module 13, a short-range communication module 14, and a location information module 15.

The input unit 20 includes a camera 21 for obtaining images or video, a microphone 22, which is one type of audio input device for inputting an audio signal, and a user input unit 30 (for example, a touch key, a push key, a mechanical key, a soft key, and the like) for allowing a user to input information. Data (for example, audio, video, image, and the like) is obtained by the input unit 20 and may be analyzed and processed by controller 80 according to device parameters, user commands, and combinations thereof.

The sensing unit 40 is typically implemented using one or more sensors configured to sense internal information of the mobile terminal, the surrounding environment of the mobile terminal, user information, and the like. For example, in FIG. 1, the sensing unit 40 is shown having a proximity sensor 41 and an illumination sensor.

If desired, the sensing unit 40 may alternatively or additionally include other types of sensors or devices, such as a touch sensor, an acceleration sensor, a magnetic sensor, a G-sensor, a gyroscope sensor, a motion sensor, an RGB sensor, an infrared (IR) sensor, a finger scan sensor, a ultrasonic sensor, an optical sensor (for example, camera 21), a microphone 22, a battery gauge, an environment sensor (for example, a barometer, a hygrometer, a thermometer, a radiation detection sensor, a thermal sensor, and a gas sensor, among others), and a chemical sensor (for example, an electronic nose, a health care sensor, a biometric sensor, and the like), to name a few. The mobile terminal 1 may be configured to utilize information obtained from sensing unit 40, and in particular, information obtained from one or more sensors of the sensing unit 40, and combinations thereof.

The output unit 50 is typically configured to output various types of information, such as audio, video, tactile output, and the like. The output unit 50 is shown having a display unit 51, an audio output module 52, a haptic module 53, and an optical output module 54.

The display unit 51 may have an inter-layered structure or an integrated structure with a touch sensor in order to facilitate a touch screen. The touch screen may provide an output interface between the mobile terminal 1 and a user, as well as function as the user input unit 30 which provides an input interface between the mobile terminal 1 and the user.

The interface unit 70 serves as an interface with various types of external devices that can be coupled to the mobile terminal 1. The interface unit 70, for example, may include any of wired or wireless ports, external power supply ports, wired or wireless data ports, memory card ports, ports for connecting a device having an identification module, audio input/output (I/O) ports, video I/O ports, earphone ports, and the like. In some cases, the mobile terminal 1 may perform assorted control functions associated with a connected external device, in response to the external device being connected to the interface unit 70.

The memory 60 is typically implemented to store data to support various functions or features of the mobile terminal 1. For instance, the memory 60 may be configured to store application programs executed in the mobile terminal 1, data or instructions for operations of the mobile terminal 1, and the like. Some of these application programs may be downloaded from an external server via wireless communication. Other application programs may be installed within the mobile terminal 1 at time of manufacturing or shipping, which is typically the case for basic functions of the mobile terminal 1 (for example, receiving a call, placing a call, receiving a message, sending a message, and the like). It is common for application programs to be stored in the memory 60, installed in the mobile terminal 1, and executed by the controller 80 to perform an operation (or function) for the mobile terminal 1.

The controller 80 typically functions to control overall operation of the mobile terminal 1, in addition to the operations associated with the application programs. The controller 80 may provide or process information or functions appropriate for a user by processing signals, data, information and the like, which are input or output by the various components depicted in FIG. 1, or activating application programs stored in the memory 60. As one example, the controller 80 controls some or all of the components illustrated in FIG. 1 according to the execution of an application program that have been stored in the memory 60.

The power supply unit 90 can be configured to receive external power or provide internal power in order to supply appropriate power required for operating elements and components included in the mobile terminal 1. The power supply unit 90 may include a battery, and the battery may be configured to be embedded in the terminal body, or configured to be detachable from the terminal body.

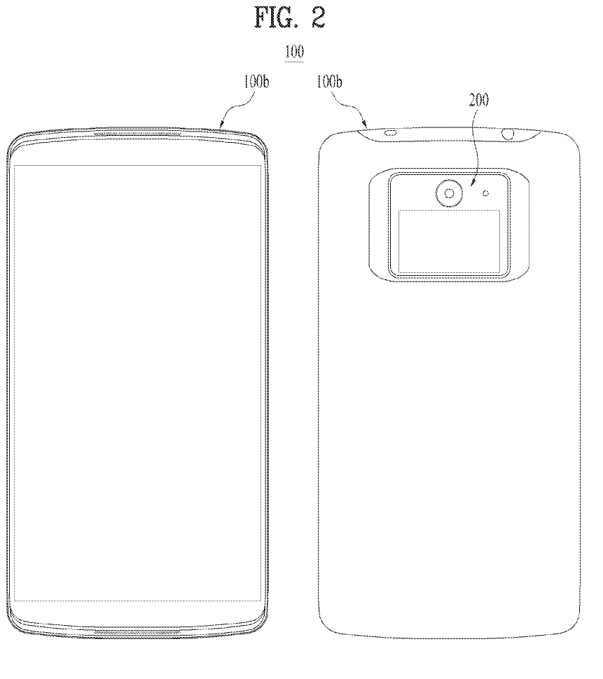

FIG. 2 is a diagram illustrating an exterior appearance of a mobile terminal according to one embodiment of the disclosure, specifically, showing a front surface and a rear surface of the mobile terminal

As shown in FIG. 2, a mobile terminal 100 includes a front portion 100a in which a display is arranged and a rear portion 100b in which a camera module 200 is arranged.

A loading recess is formed in the rear portion 100b of the mobile terminal 100 and the camera module 200 may be demounted from or mounted to the loading recess formed in the rear portion 100b of the mobile terminal 100.

Accordingly, the camera module 200 may be modulated to be mounted to or demounted from the mobile terminal 100.

For instance, the camera module 200 may include a camera unit arranged in a body and a connector arranged in the body, with being electrically connected to the mobile terminal

A demounting button may be arranged near the loading recess to separate the camera module 200 from the loading recess.

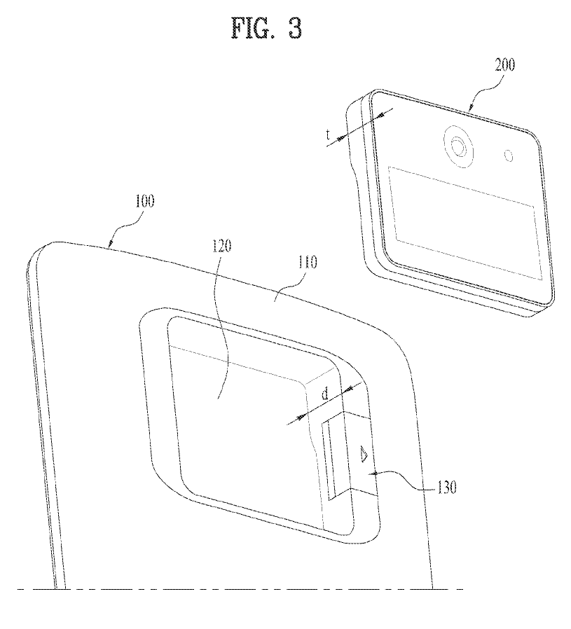

FIG. 3 is a diagram illustrating a camera module demounted from the mobile terminal

As shown in FIG. 3, the mobile terminal 100 may include a case 110 for defining an exterior appearance thereof, a loading recess 120 formed in an outer surface of the case 110 and a camera module 200.

The camera module 200 may include a body unit having a first surface inserted in the loading recess 120 and a second surface exposed outside in an opposite direction of the first surface, a camera unit arranged in the body unit and a connector arranged in the body unit, with being electrically connected to the mobile terminal

A demounting button 130 may be arranged near the loading recess 120 of the mobile terminal 100 and the demounting button 130 demounts the camera module 200 from the loading recess 120.

A connector is arranged in the loading recess 120 of the mobile terminal 100 and electrically connected to the camera module.

A ratio of a depth “d” of the loading recess 120 to a thickness “t” of the camera module may be approximately 1:0.5˜1:1.5.

The body unit of the camera module 200 may be divided into a first region in which the camera unit is arranged and a second region defined as the other region. The thickness of the first region may be different from the thickness of the second region.

For instance, the first region having the camera unit arranged therein may be thickness than the second region as the other region in the body unit of the camera module 200.

That is why a plurality of lenses arranged in the camera requires a predetermined arrangement space.

The body unit of the camera module 200 may be uniformly thick in the entire region.

In the loading recess 120 of the mobile terminal 100, the region where the camera unit of the camera module 200 may be deeper than the other region.

That is why the first region of the camera module 200 where the camera unit is arranged may be thicker than the second region corresponding to the other region except the first region.

A cover sheet may be arranged in the loading recess 120 of the mobile terminal 100 to cover an inner circuit of the mobile terminal 100.

Moreover, a support plate for supplying cover sheet may be arranged in a predetermined space of the loading recess 120 of the mobile terminal 100 and the support plate may have a central hollow portion.

In the space formed by the support plate may be further arranged in circuit parts such that spatial efficiency can be improved.

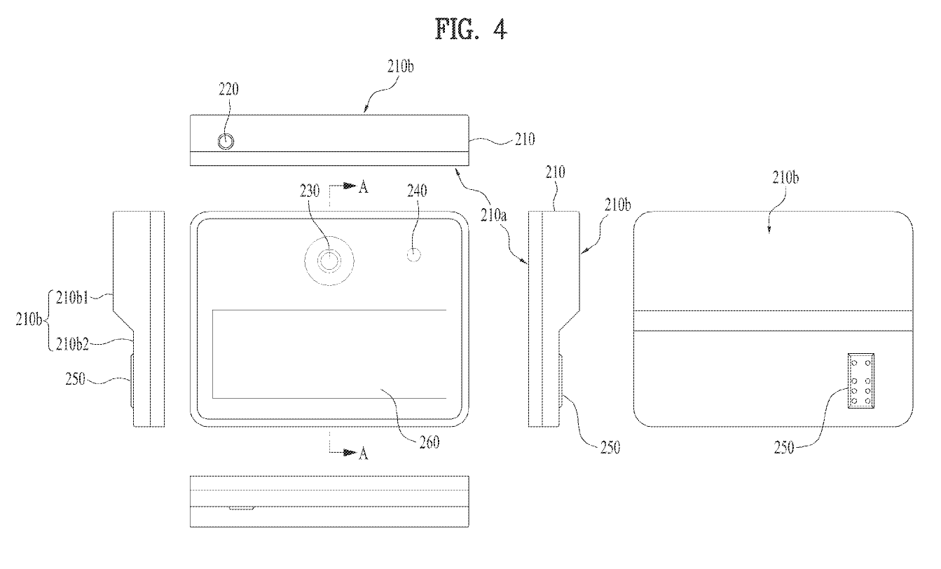

FIG. 4 is a diagram illustrating a camera module according to a first embodiment of the present disclosure. FIG. 4 shows a front surface, a rear surface, a lateral surface and upper/lower surfaces.

As shown in FIG. 4, the camera module 200 demountable from the loading recess of the mobile terminal may include a body unit 210, a camera unit 230 and a connector 250.

The body unit 210 may include a first surface 210b inserted in the loading groove and a second surface 210a exposed outside in an opposite direction of the first surface 210b.

The camera unit 230 may be arranged in the body unit 210 and lenses are exposed along the second surface 210a of the body unit 210.

A flash unit 240 for emitting a light toward the second surface 210a of the body unit 200 may be exposed via a predetermined region of the camera unit 230.

In addition, a display unit 260 may be arranged in the camera module 200 to display a variety of information. The display 260 may be exposed toward the second surface 210a of the body unit 210.

When the camera unit 230 and the display 260 are exposed via the second surface 210a of the body unit 210, the camera unit 230 may be located in an upper portion in the second surface 210a of the body unit. The display unit 260 may be located in a lower portion in the second surface 210a of the body unit 210.

At this time, the upper portion of the body unit 210 where the camera unit 230 is arranged may be thicker than the lower portion of the body unit 210 where the display unit 260 is arranged.

That is why the arrangement space occupied by the camera unit 230 is larger than the arrangement space occupied by the display unit 260.

Next, the connector 250 may arranged in the body unit and electrically connected to the mobile terminal. The connector 250 may be exposed to the first surface 210b of the body unit 210.

Here, the connector 250 may be located in a lower portion 210b in the first surface 210b of the body unit 210.

At this time, the first surface 210b of the body unit 200 may include an upper 210b1 of the first surface 210b where the connector 250 is not located and a lower 210b2 of the first surface 210b where the connector 250 is located. The upper surface of the first surface 210b and the lower surface of the first surface 210b have different heights.

A boundary surface between the upper surface of the first surface 210b and the lower surface of the first surface 210b may be inclined.

For instance, the upper surface 210b1 of the first surface 210b and the lower surface 210b2 of the first surface 210b may be parallel to the second surface 210b. A boundary surface between the upper surface 210b1 of the first surface 210b and the lower portion 210b2 of the first surface 210b may be inclined with respect to a surface of the second surface 210b.

As another example, the connector 250 may be arranged in an edge portion in the lower portion 210b2 of the first surface 210b and the present disclosure is not limited thereto.

A power key 220 may be arranged in an upper surface of the body unit 210 provided in the mobile terminal 100.

The power key 220 may be arranged in an edge portion in an upper surface of the body unit 210 and the present disclosure is not limited thereto.

The connector 250 of the camera module 250 may be exposed outside from the first surface 210b of the body unit 210 and the camera unit 230 of the camera module 200 may be exposed outside from the second surface 210a of the body unit 210.

If necessary, the connector 250 and the camera unit 230 of the camera module 200 may be exposed outside together from the first surface 210b of the body unit 210.

The body unit 210 of the camera module 200 may include a first region where the camera unit 230 is arranged and a second region corresponding to the other region. The thickness of the first region may be different from the thickness of the second region.

For instance, the first region where the camera is arranged may be thicker than the second region.

If necessary, the thickness of the first region may be the same as that of the second region.

The display unit 260 may be further arranged in the second region of the body unit 210 provided in the camera module 200. The display unit 260 may be overlapped with the connector 250 of the camera module 200.

The display unit 260 and the camera unit 230 may be exposed outside via the second surface 210a of the body unit 210. The connector 250 of the camera module 200 may be exposed outside via the first surface 210b of the body unit 210.

If necessary, the display unit 260 may be exposed outside via the second surface 210a of the body unit 210. The connector 250 and the camera unit 230 of the camera module 200 may be exposed outside together via the first surface 210b of the body unit 210.

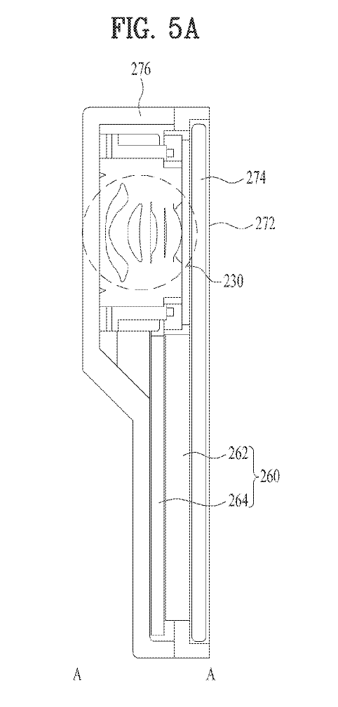

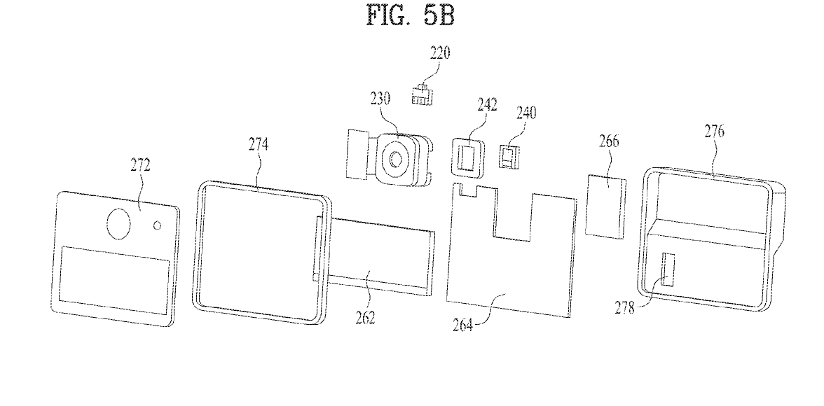

FIG. 5A is a sectional diagram along A-A of FIG. 4 and FIG. 5B is an exploded perspective diagram of FIG. 4.

As shown in FIGS. 5A and 5B, the camera unit 230 may be arranged in a predetermined portion of the camera module 200 and the display unit 260 may be arranged in the other portion of the camera module 200.

The display unit 260 may include a display panel 262 arranged in an upper surface of a circuit board 264 and a battery 266 may be arranged in a lower surface of the circuit board 264.

The camera unit 230 and the flash unit 240 may be arranged in the upper surface of the circuit board 264. The camera unit 230 and the flash unit 240 may be arranged adjacent to each other.

A pad 242 may be arranged near the flash unit 240 to protect the flash unit 240 from an external shock.

A power key 220 may be arranged beyond the camera unit 230.

An upper cover 274 may cover an upper portion of a circuit module having the camera unit 230 and the display unit 260 arranged therein. A lower cover 276 may cover a lower portion of the circuit module having the camera unit 230 and the display unit 260 arranged therein.

The lower cover 276 may include a hole configured to expose the connector of the camera module outside.

The upper cover 274 may have a penetrating hole configured to expose the camera unit 230 and the display panel 262 outside. The penetrating hole of the upper cover 274 may be covered by a cover window 272.

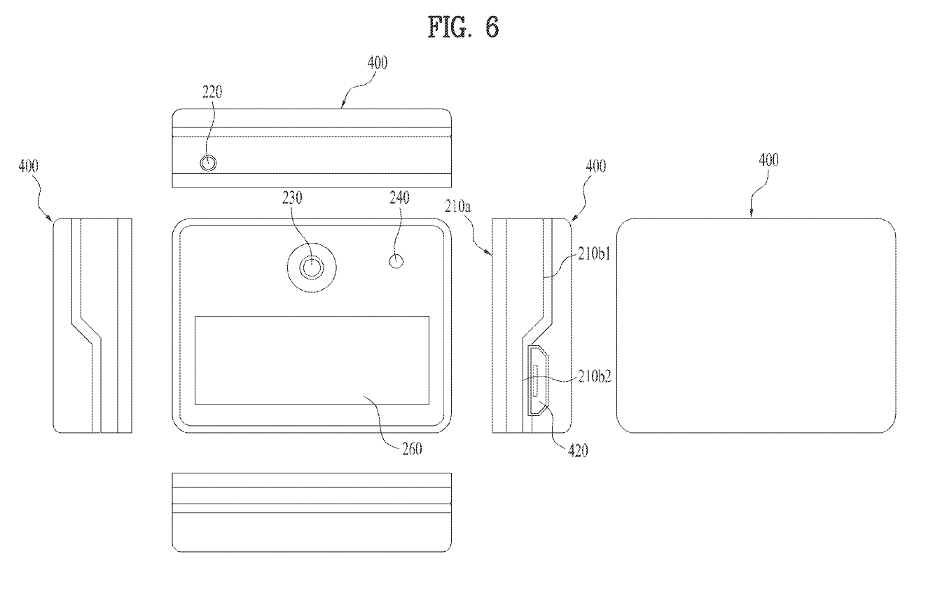

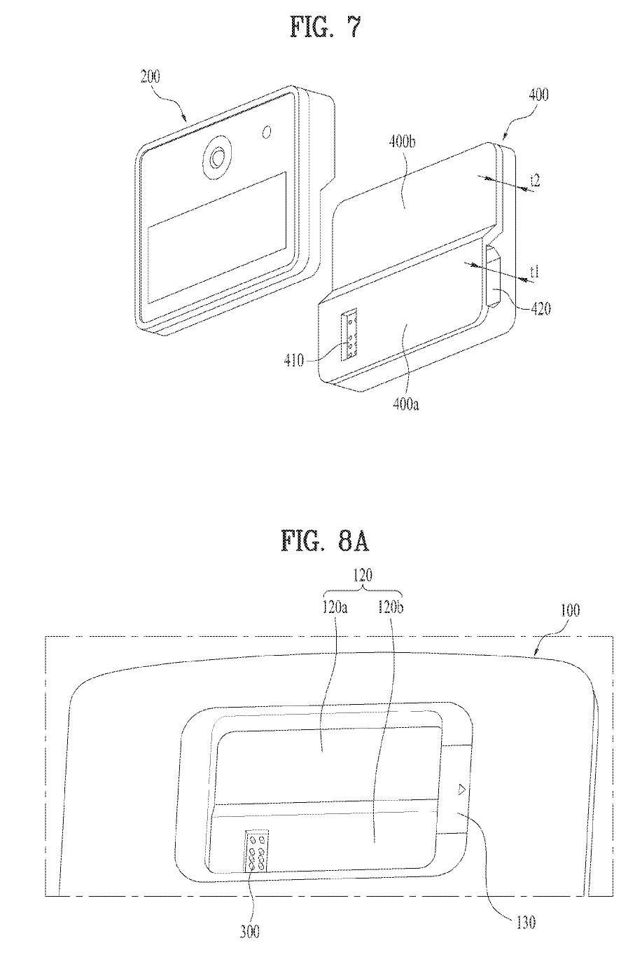

FIG. 6 is a diagram illustrating a camera module according to a second embodiment of the present disclosure. In FIG. 6 are shown a front surface, a rear surface, a lateral surface, an upper surface and a lower surface of a camera module. FIG. 7 is a diagram illustrating a battery pack of FIG. 6.

As shown in FIGS. 6 and 7, a camera module 200 may include a body unit 210, a camera unit 230 and a battery pack 240.

The body unit may include a first surface 210b inserted in a loading recess and a second surface 210a exposed outside in an opposite direction of the first surface 210b.

The camera unit 230 may be arranged in the body unit 210, with a lens exposed via the second surface 210a.

A flash unit 240 for emitting a light may be exposed via the second surface 210a of the body unit 210 may be exposed adjacent to the camera unit 230.

Moreover, a display unit 260 for displaying a variety of information may be arranged in the camera module 200 and the display unit 260 may be exposed via the second surface 210a of the body unit 210.

The battery pack 400 may be further arranged in the camera module 200 and electrically connected to the first surface 210b of the body unit 210.

A power key 220 may be arranged in an upper surface of the body unit 210 provided in the mobile terminal 100.

The body unit 210 of the camera module 200 may include a first region 210b1 where the camera unit 230 is arranged and a second region corresponding to the other portion except the camera unit 230. The thickness of the first region 210a1 may be different from that of the second region 230b2.

For instance, the first region where the camera unit 230 is arranged may be thickness than the second region.

As shown in FIG. 7, the battery pack 400 may include a third region 400a facing a connector of the camera module 200 and a fourth region 400b facing the camera unit 230 of the camera module 200. The thickness (t1) of the third region 400a may be larger than the thickness (t2) of the fourth region 400b in the battery pack 400.

The battery pack 400 may include a first connector 410 and a second connector 420.

At this time, the first connector 410 may be arranged in the third region 400a, with being electrically connected to the connector of the camera module 200. The second connector 420 may be arranged in a lateral surface of the third region 400a, with being electrically connected to an external device.

In other words, the second connector 420 of the battery pack 400 may be connected to the external power to charge the battery pack 400.

In the camera module 200 according to the second embodiment of the disclosure, the battery pack 400 electrically connected to the first surface 210b of the body unit 210 may be additionally mountable and long usage may be possible.

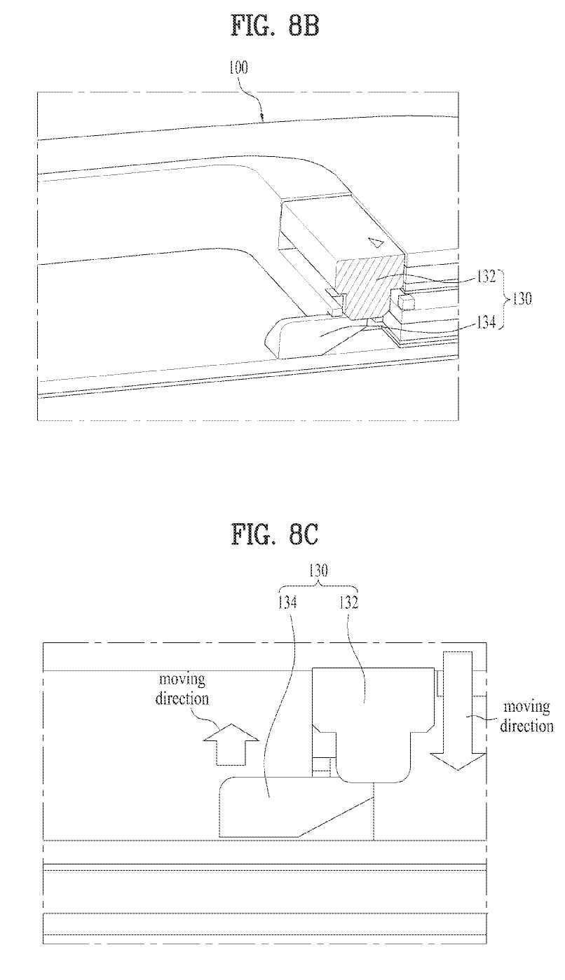

FIGS. 8A, 8B and 8C are diagrams illustrating a demounting device of the camera module.

As shown in FIGS. 8A, 8B and 8C, a demounting button 130 may be arranged near the loading recess 120 of the mobile terminal, to demount the camera module from the loading recess 120 or to mount the camera module to the loading recess 120.

For instance, the demounting button 130 may include a pushing material 132 configured to move downward when a user applies a predetermined force thereto and to return when the force is removed, and a rotary material 134 rotatable by the pushing material 132.

A central portion of the rotary material 134 is connected to a shaft and a predetermined portion of the rotary material 134 can contact with the pushing material 132.

When the pushing material 132 is moved downward, the predetermined portion of the rotary material 134 is rotationally moved downward and the other opposite portion thereof is rotationally moved upward, so as to push the camera module located in the other portion of the rotary material 134 upward.

A connector 300 electrically connected to the camera module may be arranged in the loading recess 120.

The loading recess 120 may include a fifth region 120a where the camera unit of the camera module is loaded and a sixth region 120b where a connector of the camera module is loaded. The fifth region 120a of the loading recess 120 may be thicker than the sixth region 120b of the loading recess 120.

A cover sheet may be arranged in the fifth and sixth regions 120a and 120b of the loading recess 120 to cover an internal circuit of the mobile terminal

A support plate may be arranged in the sixth region 120b of the loading recess 120 to support the cover sheet and the supply plate may have a space with an empty center.

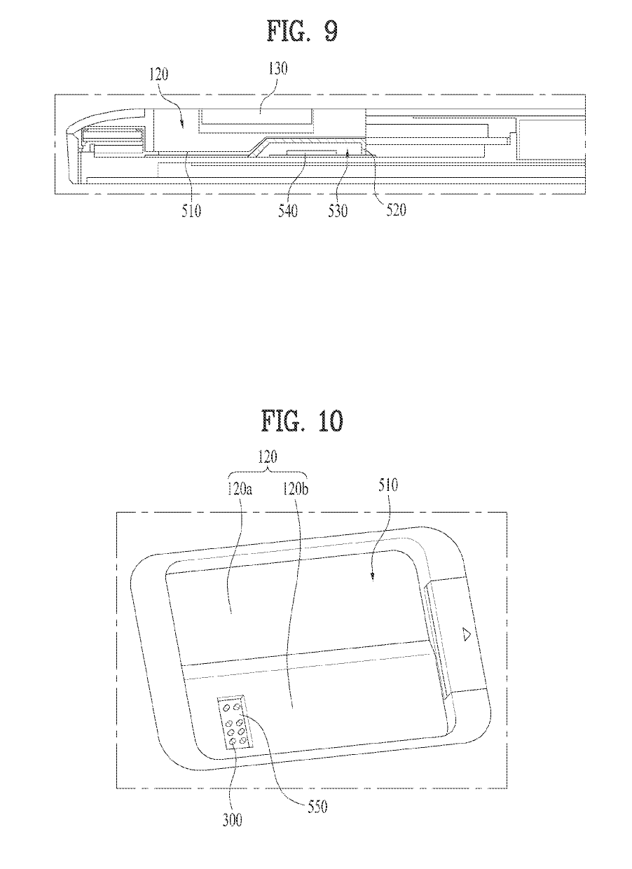

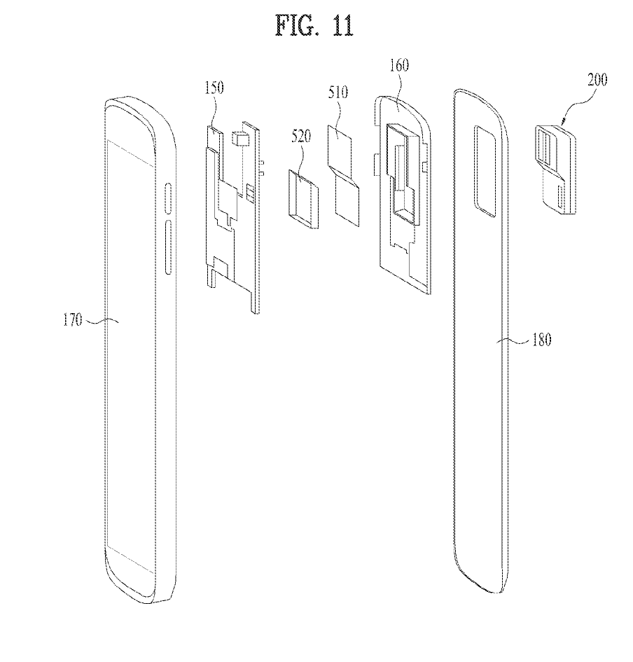

FIGS. 9, 10 and 11 are diagrams illustrating a cover sheet arranged in a loading recess. FIG. 9 is a sectional diagram and FIG. 10 is a top view and FIG. 11 is an exploded perspective diagram.

As shown in FIGS. 9, 10 and 11, a cover sheet 510 may be arranged in fifth and sixth regions 120a and 120b of the loading recess 120 to cover an internal circuit of the mobile terminal

The cover sheet 510 may have a hole 550 configured to expose a connector 300 arranged in the loading recess 120.

A support plate 520 may be arranged in the sixth region 120b of the loading recess 120 to support the cover sheet 510.

The support plate 520 may have a space 530 with an empty center (a hollow center). In the space 530 generated by the support plate 520 may be circuit parts 540 so as to improve spatial usage efficiency.

As shown in FIG. 11, the cover sheet 510 and the support plate 520 may be arranged in a circuit board 150, adjacent to each other.

The loading recess configured to load the camera module 200 therein may be formed by a middle cover 160 having an inserting hole configured to insert the camera module 200 therein.

The middle cover 160 having the circuit board 150, the cover sheet 510 and the support plate 520 may be attached to a rear surface of the case 170 provided in the mobile terminal and a battery cover 180 may be attached to the rear surface of the case 170 such that the camera module 200 may be loaded in or unloaded from the loading recess by the covers.

In the present disclosure, the camera module may be demountable from the loading recess of the mobile terminal and the mobile terminal has an effect of providing a user with easy usage.

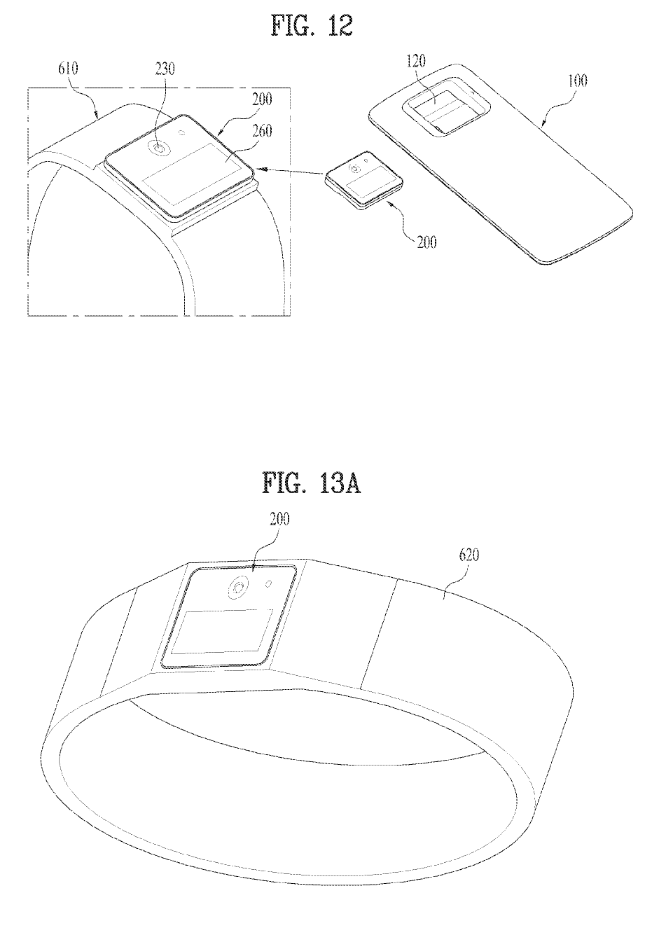

FIG. 12 is illustrating a first embodiment showing usage of the demountable camera module.

As shown in FIG. 12, the camera module 200 demounted from the loading recess 120 of the mobile terminal 100 may be mounted in a battery embedded band 610 and it may perform a watch function.

For instance, the user may mount the camera module 200 demounted from the mobile terminal 100 to the battery embedded band 610 to use the camera module as a wrist watch.

The camera module 200 may include the camera unit 200 and the display unit 260 such that music playing and video capturing may be enabled and that video and messages may sent/receive via a wire or wirelessly and also that a variety of information may be displayed on the display unit 260.

The camera module 200 may implement short range communication with the mobile terminal (e.g., Bluetooth) and it may be functioned as a mobile watch terminal

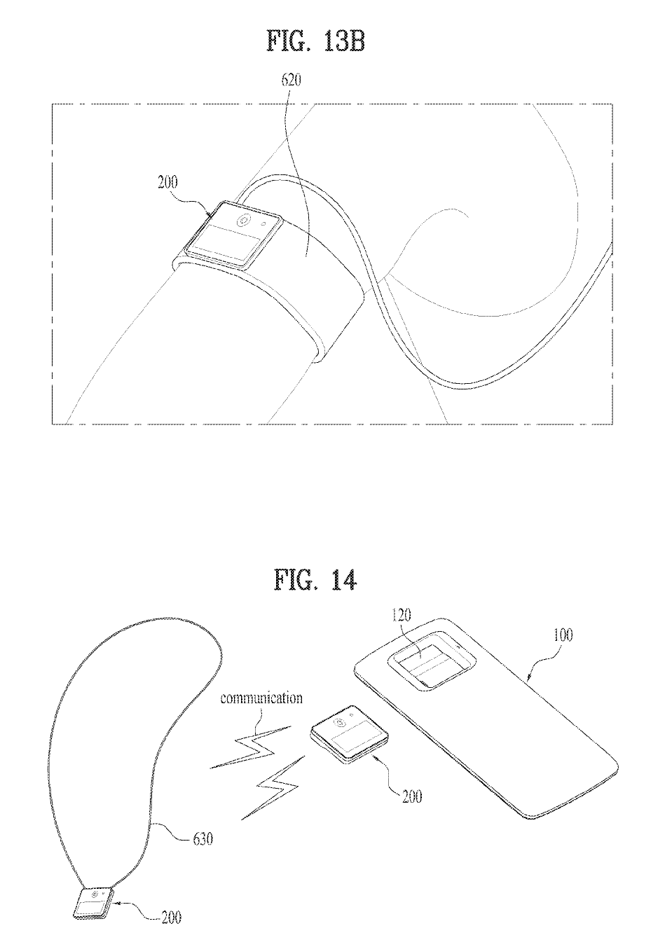

FIGS. 13A and 13B are illustrating a second embodiment showing usage of the demountable camera module.

As shown in FIG. 13A, the camera module 200 demountable from the loading recess of the mobile terminal may be mounted to an arm band 620 and functioned as a healthcare.

As shown in FIG. 13B, the arm band 620 having the camera module 200 thereto may be worn on the user's arm. When the user practice exercises, the healthcare may check the user's current health care and display various tips of information about healthcare.

In addition, the arm band 620 having the camera module 200 mounted thereto may communicate with other diverse devices and various health information can be provided to the user.

FIG. 14 is illustrating a third embodiment showing usage of the demountable camera module.

As shown in FIG. 14, the camera module 200 demounted from the loading recess 120 of the mobile terminal 100 may be mounted to a neck band 630 and functioned as a personal black box.

For instance, when the user wearing the camera module 200 mounted to the neck band 630 lives a daily life, the camera module mounted in the neck band 630 may record and store the events generated in the daily life.

The camera module 200 may include the camera unit and the display unit arranged therein and it may capture video of the personal life. Related to that, diverse information may be displayed on the display unit 260 and the camera module 200 may communicate short range communication such as Bluetooth only to receive a variety of information from the mobile terminal 100.

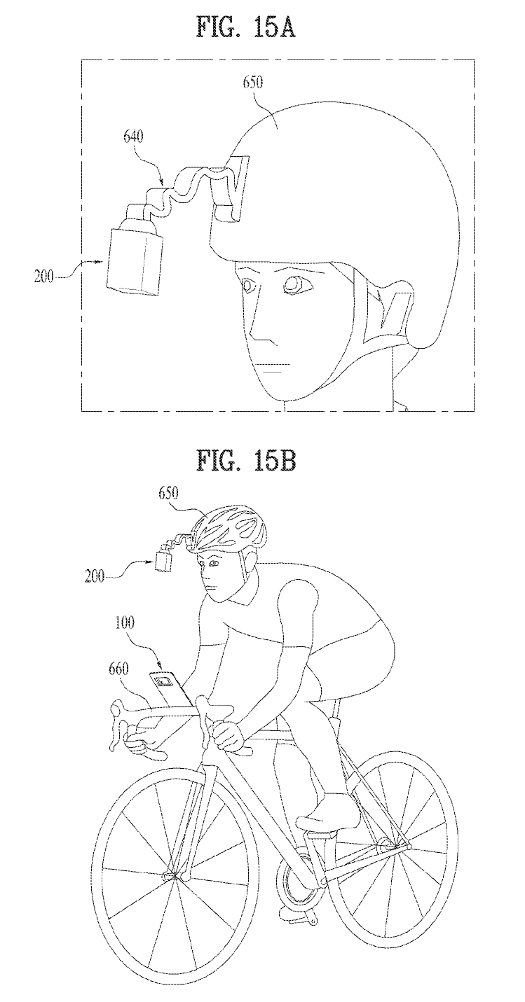

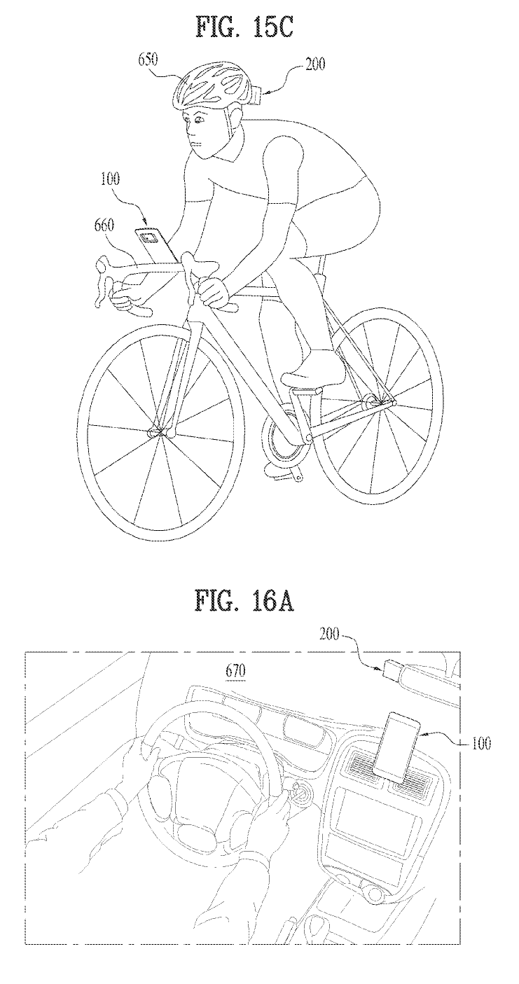

FIGS. 15A, 15B and 15C are illustrating a fourth embodiment showing usage of the demountable camera module.

As shown in FIG. 15A, the camera module 200 demounted from the loading recess of the mobile terminal may be mounted to a stand (or a rest) 640 of a helmet 650 and functioned as a front/rear camera.

As shown in FIG. 15B, the camera module 200 may be mounted to a front portion of the user's helmet 650. When the user rides a bicycle, the camera module 200 may photograph the user's front situation.

The camera module 200 may communicate with the mobile terminal 100 held to a handle 660 of the bicycle and transmit the captured vide to the mobile terminal 100.

Accordingly, the user may check the front situation through the mobile terminal 100 held to the handle 660 of the bicycle and safe riding can be possible.

The camera module 200 may store mileage records and information based on the front situation capturing and it may be functioned as a black box.

As shown in FIG. 15C, the camera module 200 may be mounted to a back side of the user's helmet 650. When the user rides a bicycle, the camera module may capture the user's rear situation.

The camera module 200 may communicate with a mobile terminal 100 held to a handle 660 of the bicycle and sent the captured rear images.

Accordingly, the user can check rear situations via the mobile terminal 100 held to the handle 660 of the bicycle and understand risk elements such that the safe riding may be possible.

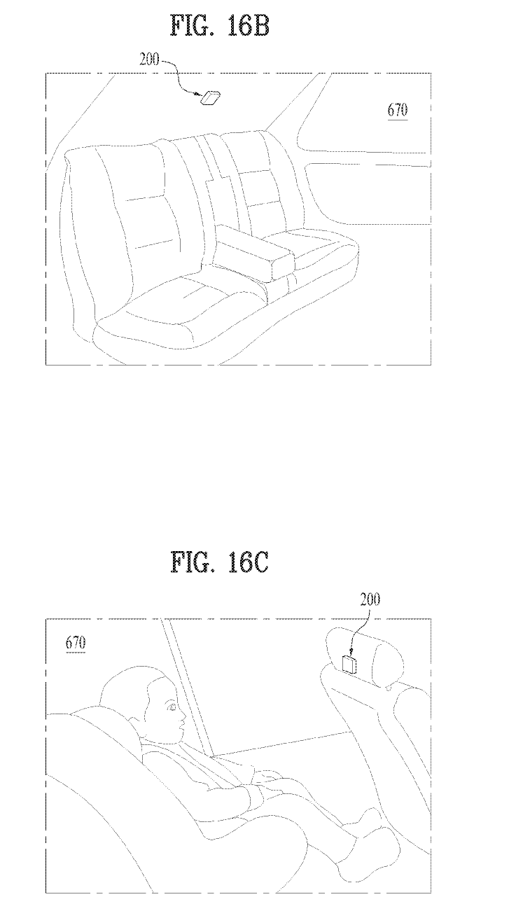

FIGS. 16A, 16B and 16C are illustrating a fifth embodiment showing usage of the demountable camera module.

As shown in FIGS. 16A and 16B, the camera module 200 demounted from the loading recess of the mobile terminal 100 may be mounted to at least one of front and rear windows of a vehicle 670 and functioned as a black box of a vehicle.

The camera module 200 may capture front and rear situations of the vehicle 670 and communicate with a mobile terminal 100 held in the vehicle 670 to send the captured images.

Accordingly, the user can check the front and rear situations via the mobile terminal 100 held in the vehicle 670, only for safe driving.

The camera module 200 may store mileage records and information based on the captured front and rear situations and it may be functioned as a black box.

As shown in FIG. 16C, the camera module 200 may be held to a rear surface of a front seat in the vehicle 670 to capture a state of a child seated on a back seat.

The camera module 200 may communicate with a mobile terminal 100 held in the vehicle 670 and sent the captured image of the child to the mobile terminal 100.

Accordingly, the user can check the child seated on the back seat via the mobile terminal 100 and understand risk elements, such that safe driving may be possible.

The mobile terminal 100 may be functioned as a navigation for the vehicle and display the captured images sent from the camera module 200 together. The mobile terminal 100 may display the navigation function and the display function simultaneously or alternatively/

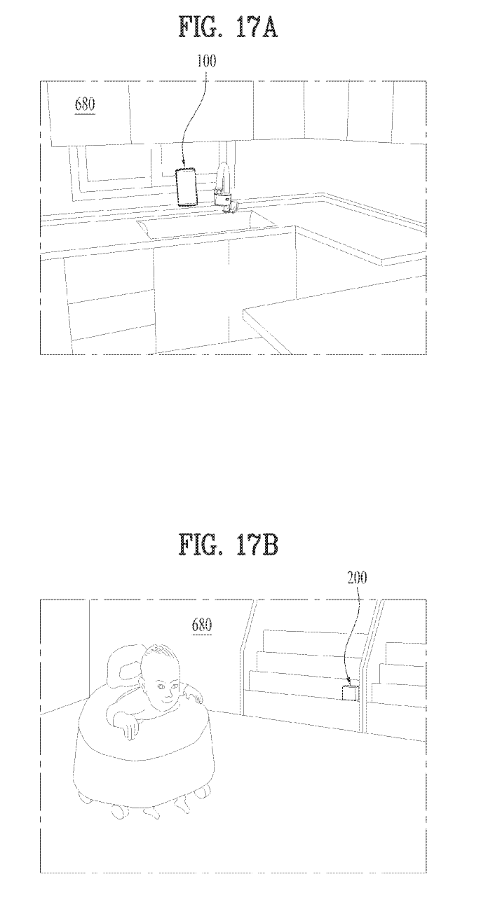

FIGS. 17A and 17B are illustrating a sixth embodiment showing usage of the demountable camera module.

As shown in FIGS. 17A and 17B, the camera module 200 demounted from the loading recess of the mobile terminal 100 may perform a function of an observation camera in a house.

For instance, when a kitchen and a living room are separated in a house 680, the mobile terminal 100 is held in a kitchen as shown in FIG. 17A. When the camera module 200 demounted from the mobile terminal 100 is held in the living room where a child or infant is staying, the user can observe the child or infant staying in the living room, with performing household chores in the kitchen.

In other words, the camera module 200 may be mounted in any places in the house and capture the child or infant's state.

The camera module 200 may communicate with the mobile terminal 100 and send the captured video to the mobile terminal 200.

The user can check the child's current state even at the place where the child is not seen and understand risk elements so as to protect the child or infant.

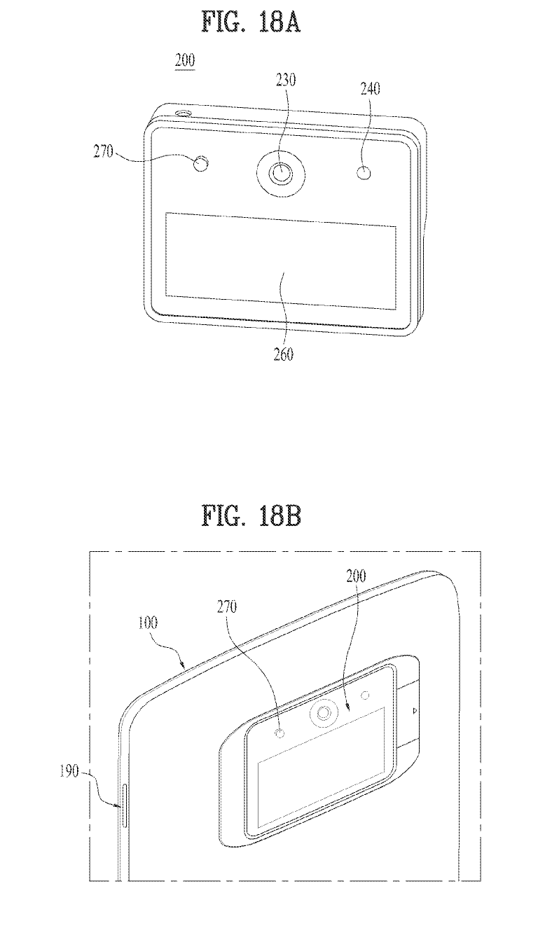

FIGS. 18A and 18B are illustrating a first embodiment of a user interface provided in the mobile terminal according to the present disclosure.

As shown in FIG. 18A, a camera module 200 may include a camera unit 230 and a display unit 260.

The camera unit 230 may have a lens exposed to a front surface of the camera module 200 and a flash 230 may be exposed to a front surface of the camera module 200, with arranged near the camera unit 230. The display unit 260 may be exposed via the front surface of the camera module 200, under the camera unit 230.

Moreover, a power button 270 for ON/OFF of the power may be arranged in the other side next to the camera unit 230 to the front surface of the camera module 200.

As mentioned above, the camera module 200 having the power button 270 may be loaded in the loading recess of the mobile terminal 100.

When the camera module 200 having the power button 270 mounted to the mobile terminal 100 as shown in FIG. 18B, the mobile terminal may switch the power button 270 of the camera module 200 to a power button 190 of the mobile terminal 100 and the power button 190 of the mobile terminal 100 over to a camera button.

The mobile terminal 100 may include a sensing unit configured to sense the mounting or demounting of the camera module 200 and a control unit for controlling the switching of the power button 270 of the camera module 200 over to the power button 190 of the mobile terminal 100 and the switching of the power button 190 over to the camera button of the mobile terminal 100 based on a sensing signal sent from the sensing unit, when the camera module 200 is mounted to the mobile terminal 100.

Alternatively, the mobile terminal 100 may include the control unit configured to switch the power button 270 of the camera module 200 over to the power button 190 of the mobile terminal, when the camera module 200 is mounted to be electrically connected to the mobile terminal, without the sensing unit for sensing the demounting of the camera module 200.

Accordingly, when the camera module is mounted to the mobile terminal, switching is performed between the function button of the camera module and the function button of the mobile terminal and the mobile terminal according to the disclosure may provide the user with convenient and easy usable function buttons.

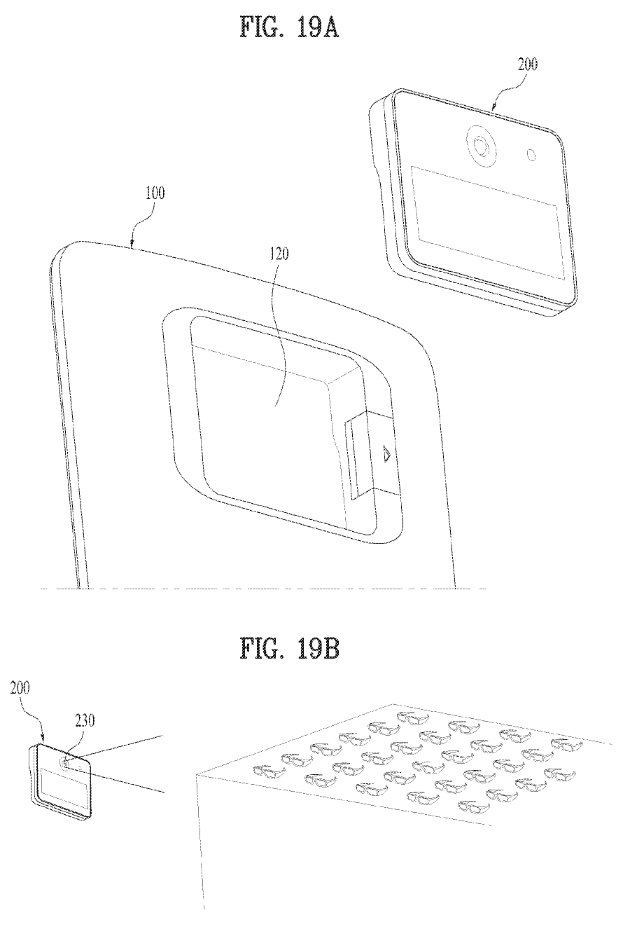

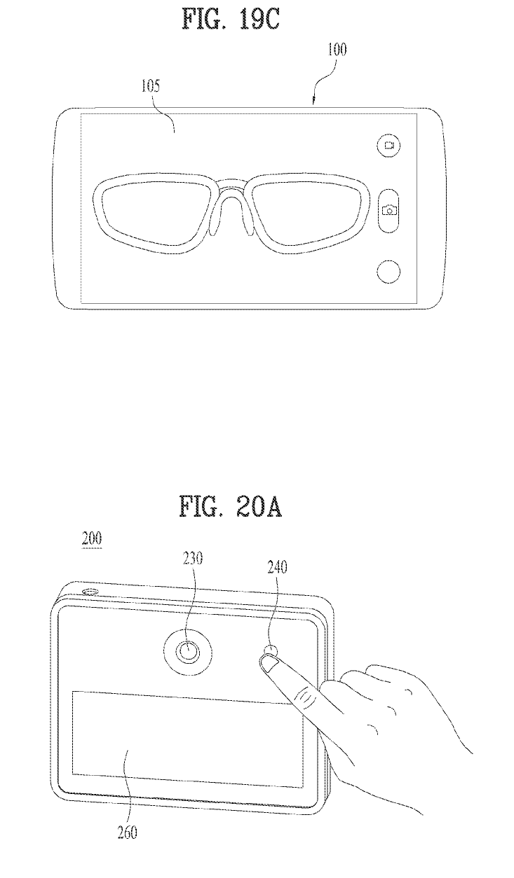

FIGS. 19A, 19B and 19C are illustrating a second embodiment of a user interface provided in the mobile terminal according to the present disclosure.

As shown in FIG. 19A, a camera module 200 may be demounted from the loading recess 120.

As shown in FIG. 19B, the demounted camera module 200 may capture the external environment the user desires to, using a camera unit 230.

When demounted from the mobile terminal 100, the camera module 200 drives the camera unit 230 automatically and controls to send the video captured by the camera unit 230.

When the camera module 200 is demounted, the mobile terminal 100 shown in FIG. 19C may receive and display the video captured from the camera module 200 on the display 105.

The mobile terminal 100 may include a receiving unit configured to receive the video from the camera module 200, a display 105 configured to displaying the received video, a sensing unit configured to sense the demounting of the camera module 200 and a control unit configured to receive and display the video captured by the camera module 200 on the display 105.

The camera module 200 may include the camera unit 230 configured to capture the external environment, a sending unit configured to transmit the captured video of the camera unit, the sensing unit configured to sense the demounting from the mobile terminal, and a camera control unit configured to control the camera unit 230 driven based on a sensing signal of the sensing unit, when the camera module 200 is demounted from the mobile terminal 100, to control the video captured by the camera unit 230 transmitted to the mobile terminal 100.

When the camera module is demounted form the mobile terminal, the video captured by the camera module may be displayed immediately and the mobile terminal according to the present disclosure requires no unnecessary operations such that usage of the mobile terminal may be convenient.

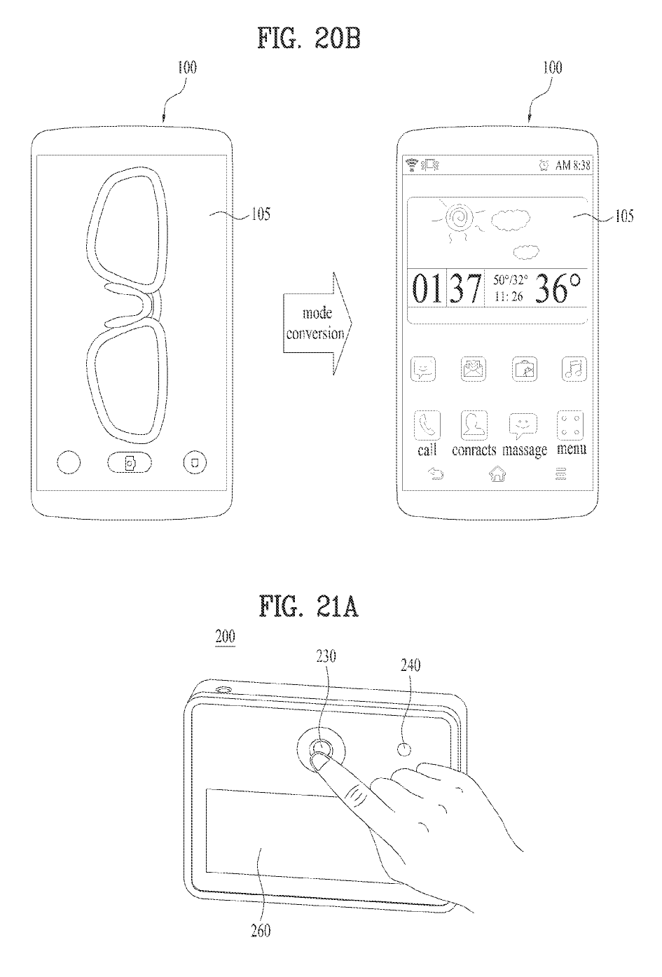

FIGS. 20A and 20B are illustrating a third embodiment of a user interface provided in the mobile terminal according to the present disclosure.

As shown in FIG. 20A, the camera module 200 may include a camera unit and a display unit and further a sensing unit 280.

The sensing unit 280 may be exposed to a front surface of the camera module 200. For instance, the sensing unit 280 may be a proximity sensor and examples of the sensing unit 280 may include other various sensors.

The camera module 200 demounted from the mobile terminal 100 may recognize an obstacle approaching the camera module 200 through the sensing unit 280, when capturing an external environment. In a preset time period, the camera module 200 may control a mode switch signal to be transmitted to the mobile terminal

The camera module 200 may transmit only a signal sensed by the sensing unit, without generating the mode switch signal.

As shown in FIG. 20B, the mobile terminal 100 may control the image displayed on the display 105 to be switched to a mobile terminal mode from a camera mode, when receiving the mode switch signal or the sensing signal from the camera module 200.

The mobile terminal 100 may include a receiving unit for receiving the video from the camera module 200, a display 105 configured to display the received video and a control unit configured to control the video displayed on the display 105 to be switched over to the mobile terminal mode from the camera mode, when receiving the mode switch signal or the sensing signal.

The camera module 200 may include a camera unit configured to capture an external environment, a transmitting unit configured to transmit the video captured by the camera unit, a sensing unit 280 configured to sense the external environment and a control unit configured to control a mode switch signal to be transmitted to the mobile terminal, when the signal sensed by the sensing unit is kept for a preset time period.

Alternatively, the camera module 200 may transmit only the sensing signal sensed by the sensing unit, with generating no mode switch signal.

When the mode switch signal is received from the camera module, the video displayed on the display may be switched over to the mobile terminal mode from the camera mode and the user is not required to perform unnecessary operations. Accordingly, the mobile terminal according to the present disclosure may have an effect of improved convenience.

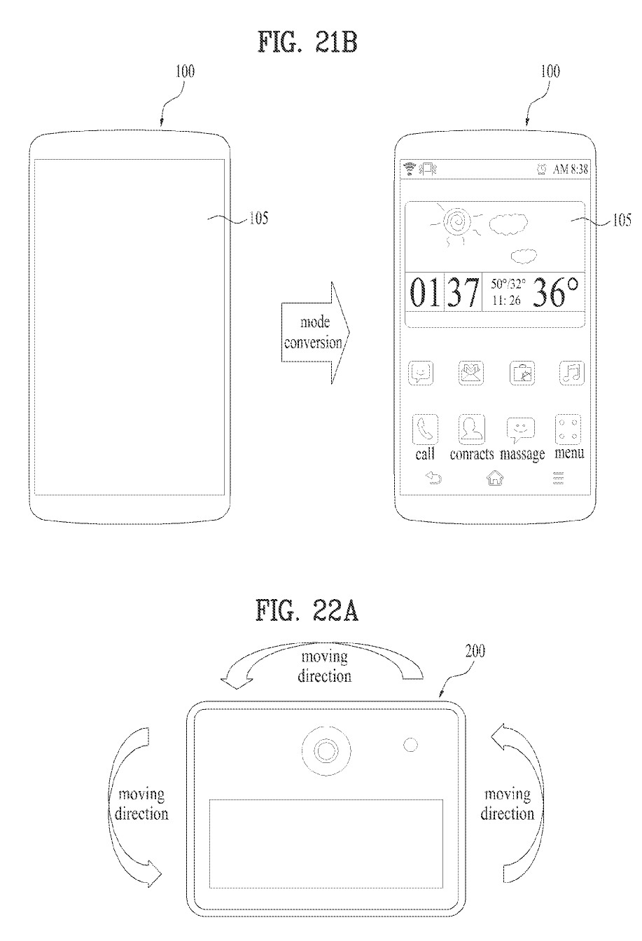

FIGS. 21A and 21B are illustrating a fourth embodiment of a user interface provided in the mobile terminal according to the present disclosure.

As shown in FIG. 21A, a camera module 200 may include a camera unit 230 and a display unit.

The camera module 200 demounted from the mobile terminal 100 may control a mode switch signal to be transmitted to the mobile terminal 100, when the video captured by the camera unit 230 is kept as a black image for a preset time period by an obstacle blocking the camera unit 230.

Alternatively, the camera module 200 may transmit only the black image, without generating the mode switch signal.

As shown in FIG. 21B, the mobile terminal 100 may control the image displayed on the display 105 to be switched over to a mobile terminal mode from a camera mode, unless receiving a video signal from the camera module 200 for a preset time period.

The mobile terminal 100 may include a receiving unit configured to receive a video from the camera module 200, a display 105 configured to display the received video and a control unit configured to control the image displayed on the display 105 to be switched over to a mobile terminal mode from a camera mode, unless receiving the video signal from the camera module 200 for a preset time period.

The camera module 200 may include a camera unit 230 configured to capture an external environment, a transmitting unit configured to transmit the video captured by the camera unit 230 and a camera control unit configured to control a mode switch signal to be transmitted to the mobile terminal 100, when the video transmitted from the camera unit 230 is kept as a black video for a preset time period.

Alternatively, the camera module 200 may transmit only the black video, without generating the mode switch signal.

When the video signal is not received from the camera module for a preset time period, the video displayed on the display may be switched over to the mobile terminal mode from the camera mode. Accordingly, the user is not required to perform unnecessary operations and provided with an effect of improved convenience.

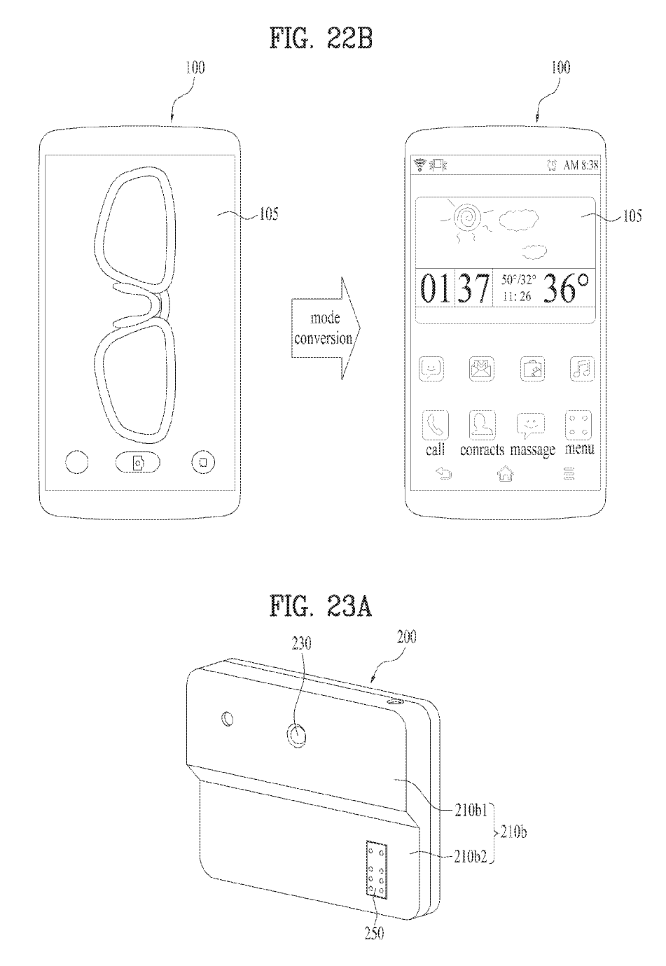

FIGS. 22A and 22B are illustrating a fifth embodiment of a user interface provided in the mobile terminal according to the present disclosure.

As shown in FIG. 22A, a camera module 200 may include a camera unit and a display unit. The camera module 200 may further include a gyrosensor.

The camera module 200 demounted from the mobile terminal 100 may recognize that differences of displacements in directions of X, Y and Z axes are generated continuously for a preset time period through the gyrosensor, when shook for a preset time period, with no directionality while capturing an external environment.

The camera module 200 may transmit a signal sensed by the gyrosensor to the mobile terminal directly. When the signal sensed by the gyrosensor is kept for a preset time period, the camera module 200 may control a mode switch signal to be transmitted to the mobile terminal 100.

Hence, as shown in FIG. 22B, the mobile terminal 100 receives the mode switch signal from the camera module 200 and controls an image displayed on the display 105 to be switched over to a mobile terminal mode from a camera mode.

The mobile terminal 100 may determine whether displacement differences of the signals sensed by the gyrosensor of the camera module 200 in directions along X, Y and Z axes are generated for a preset time period continuously and controls the video displayed on the display 105 to be switched over to a mobile terminal mode from a camera mode based on the result of the determination.

Alternatively, the mobile terminal 100 may include a receiving unit configured to receive video from the camera module 200, a display 105 configured to display the received video and a control unit configured to control the video displayed on the display 105 to be switched over to a mobile terminal mode from a camera mode, when receiving a mode switch signal from the camera module 200.

The camera module 200 may include a camera unit configured to capture an external environment, a transmitting unit configured to transmit the video captured by the camera unit, a sensing unit configured to sense the motion of the camera module and a control unit configured to control the mode switch signal to be transmitted to the mobile terminal 100, when the signal sensed by the sensing unit is kept for a preset time period.

The mobile terminal according to the present disclosure may automatically recognize that the video capturing environment is not good based on the motion of the camera module. When receiving the mode switch signal from the camera module, the mobile terminal can switch the video displayed on the display over to the mobile terminal mode from the camera mode and requires the user no unnecessary operations, such that the user may be provided with an effect of convenience in use.

In a sixth embodiment of a user interface provided in the mobile terminal according to the present disclosure, the mobile terminal may control the video displayed on the display to be switched over to a mobile terminal mode from a camera mode, when the communication between the camera module and the mobile terminal is disconnected in case a distance between the mobile terminal and the camera module capturing an external environment is out of a reference distance after the camera module is demounted from the mobile terminal

Unless receiving the video signal from the camera module, the mobile terminal may switch the video displayed on the display over to the mobile terminal mode from the camera mode such that it may require the user no unnecessary operations and provide the user with the convenience in use.

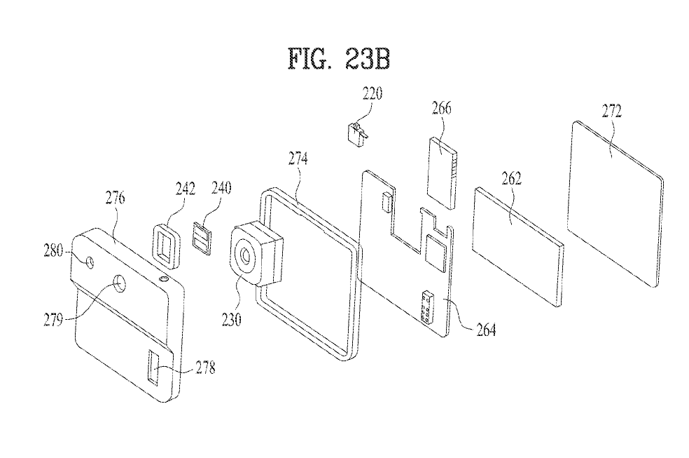

FIGS. 23A and 23B are diagrams illustrating a camera module according to a second embodiment of the present disclosure. FIG. 23A is a perspective diagram and FIG. 23B is an exploded perspective diagram.

As shown in FIGS. 23A and 23B. A camera module 200 demountable from a loading recess of a mobile terminal may include a body unit 210, a camera unit 230 and a connector 250.

The body unit 210 may include a first surface 210b inserted in the loading recess and a second surface exposed outside in an opposite direction of the first surface 210b.

The camera unit 230 may be arranged in the body unit 210 and a lens of the camera unit 230 may be exposed via the first surface 210b of the body unit 210.

A flash 240 may be arranged near the camera unit 230 to emit a light along the first surface 210b of the body unit 210, with exposed outside.

The connector 250 may be arranged in the body unit 210, with being electrically connected to the mobile terminal, and it may be exposed via the first surface 210b of the body unit 210.

In addition, a display unit may be arranged in the camera module 200 to display a variety of information. The display unit may be exposed via the second surface 210a of the body unit 210.

When the camera unit 230 and the connector 250 are exposed via the first surface 210b of the body unit 210, the camera unit 230 may be located in an upper end portion 210b1 of the first surface 210b provided in the body unit 210 and the connector 250 may be located in a lower portion 210b2 of the first surface 210b provided in the body unit 210.

At this time, the upper portion of the body unit 210 where the camera unit 230 is located may be thicker than the lower portion of the body unit 210 where the connector 250 is located.

That is why the arrangement space occupied by the camera unit 230 is larger than the arrangement space occupied by the connector 250.

Specifically, the first surface 210b may include the upper portion 210ba of the first surface 210b where the camera unit 230 is located and the lower portion 210b2 of the first surface 210b where the connector 250 is located. The height of the upper portion 210b1 possessed by the first surface 210b may be different from the height of the lower portion possessed by the first surface 210b.

A boundary surface between the upper portion surface of the first surface 210b and the lower portion surface of the first surface 210b may be inclined.

For instance, the upper portion surface of the first surface 210b and the lower portion surface of the first surface 210b may be parallel to a surface of the second surface. The boundary surface between the surfaces of the upper and lower portions 210b1 and 210b2 possessed by the first surface 210b may be inclined with respect to the surface of the second surface.

Alternatively, the connector 250 may be arranged in an edge region of the lower portion 210b2 possessed by the first surface 210b and the position is not limited thereto.

A power key may be arranged in an upper surface of the body unit 210 provided in the camera module 200.

The power key may be arranged in an edge region of the upper surface possessed by the body unit 210 and the position is not limited thereto.

The connector 250 and the camera unit 230 provided in the camera module 200 may be exposed outside via the first surface 210b of the body unit. The display of the camera module 200 may be exposed outside via the second surface of the body unit 210.

As shown in FIG. 23B, in an upper surface of a circuit board 264 may be arranged in a display panel 262, a battery 266 and a cover window 272. In a lower surface of the circuit board 264 may be arranged the camera 230 and the flash 240, adjacent to each other.

A pad 242 may be arranged near the flash 240 to protect the flash 240 from an external shock.

A power key 220 may be arranged beyond the camera unit 230.

An upper cover 274 may cover an upper portion of the circuit module where the display panel 262 is arranged. A lower cover 276 may cover a lower portion of the circuit module where the camera unit 230 is arranged.

A plurality of holes may be formed in the lower cover 276 to expose the connector, the camera unit and the flash of the camera module outside.

A penetrating hole may be formed in the upper cover 274 to expose the display panel 262 outside. The penetrating hole of the upper cover 274 may be covered by a cover window 272.

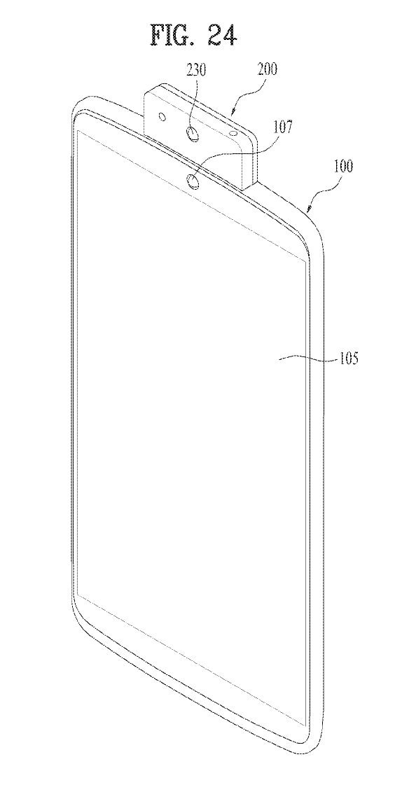

FIG. 24 is a diagram illustrating a mobile terminal having the camera module according to the second embodiment mounted thereto.

As shown in FIG. 24, the mobile terminal 100 may include a camera 107 configured to capture an external environment.

The camera 107 of the mobile terminal 100 and the camera unit 230 of the camera module 200 may be arranged along the same direction.

At this time, the camera 107 of the mobile terminal 100 and the camera unit 230 of the camera module 200 may be arranged, spaced apart a predetermined distance from each other.

When the camera 107 of the mobile terminal 100 and the camera unit 230 of the camera module 200 are arranged toward the same direction, the distance between the two cameras is fixed as far as a distance percentage capable of enabling the user to feel 3-dimentional effect so as to enable 3-dimetional video capturing.

Accordingly, the camera of the mobile terminal is spaced apart a predetermined distance from the camera unit of the camera module and the two cameras are arranged toward the same direction, when capturing the external environment, such that the user can be provided with a three dimensional image.

According to at least one of the embodiments, the camera module demountable from the loading recess of the mobile terminal may be provided and the user may be provided with diverse convenience in using the mobile terminal

Furthermore, when the camera module is demounted from the mobile terminal, the video captured by the camera module may be immediately displayed. The user may not be required to perform the unnecessary operations for driving the camera module and the user may be provided with improved convenience in use.

Still further, when receiving the mode switch signal from the camera module, the mobile terminal may switch the video displayed on the display over to the mobile terminal mode from the camera mode. Accordingly, the user may not be required to perform the unnecessary operations and the user may be provided with the improved convenience in use.

Still further, unless receiving the video signal for a preset time period from the camera module, the mobile terminal may switch the video displayed on the display over into the mobile terminal mode from the camera mode. Accordingly, the user may not be required to perform the unnecessary operations for driving the camera module and the user may be provided with improved convenience in use.

Still further, the camera of the mobile terminal and the camera unit of the camera module are spaced apart a predetermined distance from each other, arranged toward the same direction, and capture the external environment. Accordingly, the user may be provided with the three dimensional effect.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A mobile terminal comprising:
a case configured to define an exterior appearance thereof;
a loading recess formed in an outer surface of the case; and
a camera module mountable to and demountable from the loading recess,
wherein the camera module comprises,
a body unit comprising a first surface inserted in the loading recess and a second surface exposed in an opposite direction of the first surface;
a camera unit arranged in the camera unit; and
a connector arranged in the body unit, with connected to the mobile terminal electrically.

2. The mobile terminal of claim 1, wherein a demounting button is arranged near the loading recess to demount the camera module from the loading recess.

3. The mobile terminal of claim 1, wherein the connector electrically connected to the camera module is arranged in the loading recess.

4. The mobile terminal of claim 1, wherein a ratio of the depth of the loading recess to the thickness of the camera module is 1:05-1:1.5.

5. The mobile terminal of claim 1, wherein the connector of the camera module is exposed outside via a first surface of the body unit, and
the camera unit of the camera module is exposed outside via a second surface of the body unit.

6. The mobile terminal of claim 1, wherein the connector and the camera unit of the camera module are exposed outside via a first surface of the body unit together.

7. The mobile terminal of claim 1, wherein the body unit of the camera module comprises a first region in which the camera unit is arranged and a second region corresponding to the other region, and
the thickness of the first region is different from the thickness of the second region.

8. The mobile terminal of claim 7, wherein the first region in which the camera unit is arranged is thicker than the second region.

9. The mobile terminal of claim 7, wherein a display unit is arranged in the second region of the body unit provided in the camera module.

10. The mobile terminal of claim 9, wherein the display unit is overlapped with the connector of the camera module.

11. The mobile terminal of claim 9, wherein the display unit and the camera unit are exposed outside via a second surface of the body unit together, and
the connector of the camera module is exposed outside via a first surface of the body unit.

12. The mobile terminal of claim 9, wherein the display unit is exposed outside via a second surface of the body unit, and
the connector and the camera unit of the camera module are exposed outside via a first surface of the body unit together.

13. The mobile terminal of claim 1, wherein the camera module further comprises,
a battery pack electrically connected to the first surface of the body unit.

14. The mobile terminal of claim 13, wherein the battery pack comprises,
a third region facing a connector of the camera module and a fourth region facing a camera unit of the camera module, and
the third region of the battery pack is thicker than the fourth region of the battery pack.

15. The mobile terminal of claim 14, wherein the battery pack comprises,
a first connector arranged in a front surface of the third region, with connected to the connector of the camera module; and
a second connector arranged in a lateral surface of the third region, with connected to an external device electrically.

16. The mobile terminal of claim 1, wherein the loading recess comprises,
a fifth region in which the camera unit of the camera module is loaded and a sixth region in which the connector of the camera module is loaded, and
the fifth region of the loading recess is thicker than the sixth region of the loading recess.

17. The mobile terminal of claim 16, wherein a cover sheet is arranged in the fifth and sixth regions of the loading recess to cover an internal circuit of the mobile terminal, and
a support plate is arranged in the sixth region of the loading recess to support the cover sheet, and
the support plate comprises an empty central space.

18. The mobile terminal of claim 1, further comprising:
a control unit configured to switch a power button of the camera module over to a power button of the mobile terminal, when the camera module is mounted to the mobile terminal, and to switch the power button of the mobile terminal over to a camera button.

19. The mobile terminal of claim 1, further comprising:
a control unit configured to control a video displayed on the display unit to be switched over to a mobile terminal mode from a camera mode, when receiving a mode switch signal from the camera module.

20. The mobile terminal of claim 1, further comprising:
a camera configured to capture an external environment,
wherein the camera of the mobile terminal and the camera unit of the camera module are arranged toward the same direction, and
the camera of the mobile terminal and the camera unit of the camera module are spaced apart a predetermined distance from each other.
